(19) United States
(12) Patent Application Publication
(10) Pub. No.: US 2025/0331387 A1
(43) Pub. Date: Oct. 23, 2025

(54) DISPLAY DEVICE

(71) Applicant: Samsung Display Co., Ltd., Yongin-si (KR)

(72) Inventors: Jeong Soo KIM, Yongin-si (KR); Gi Hoon YANG, Yongin-si (KR); Min Seok LEE, Yongin-si (KR); Suk Kung CHEI, Yongin-si (KR)

(73) Assignee: Samsung Display Co., Ltd., Yongin-si (KR)

(21) Appl. No.: 18/950,837

(22) Filed: Nov. 18, 2024

(30) Foreign Application Priority Data
Apr. 19, 2024 (KR) 10-2024-0052708

(51) Int. Cl. H10K 59/38; H10K 59/80

(52) U.S. Cl. CPC H10K 59/38; H10K 59/873; H10K 59/8792

(57) ABSTRACT

A display device includes: a display area including a light emitting element including a light emitting layer; a non-display area; a pixel defining layer including a first opening, a portion of the light emitting layer being in the first opening; an encapsulation layer on the light emitting element; a partition wall on the encapsulation layer and including a second opening overlapping the first opening; a light control pattern layer in the second opening; a bank pattern layer in the non-display area and in a same layer as the partition wall, the bank pattern layer and the partition at least partially bounding a third opening; and a step difference compensation pattern layer in the third opening. A difference in height between the partition wall and the light control pattern layer is smaller than a difference in height between the bank pattern layer and the step difference compensation pattern layer.

### CROSS-REFERENCE TO RELATED APPLICATION(S)

This U.S. non-provisional patent application claims priority to and the benefits of Korean Patent Application No. 10-2024-0052708, under 35 U.S.C. § 119, filed in the Korean Intellectual Property Office on Apr. 19, 2024, the entire contents of which are hereby incorporated by reference.

### BACKGROUND

### 1. Technical Field

The disclosure generally relates to a display device.

### 2. Description of the Related Art

With the development of information technologies, the importance of a display device, which may be a connection medium between a user and information is increasing. Accordingly, research and development of display devices have been continuously conducted.

A display device may include multiple layers. Protecting a display device from external influence is an area of continued interest. For example, in a case that cracks occur in a display device, a risk, such as deterioration of display quality, may occur.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

One or more aspects provide a display device in which device stability is capable of being improved, thereby improving display quality and having a structure rigid (or robust) against external influence.

Additional aspects will be set forth in the detailed description, which follows, and in part, will be apparent from the disclosure, or may be learned by practice of the disclosed embodiments and/or the claimed subject matter.

According to an aspect, a display device includes a display area, a non-display area, a pixel defining layer, a first encapsulation layer, a partition wall, a light control pattern layer, a bank pattern layer, and a step difference compensation pattern layer. The display area includes pixels. At least one of the pixels includes a light emitting element, which includes a light emitting layer. The non-display area is outside of the display area in a view in a direction. The pixel defining layer includes a first opening. At least a portion of the light emitting layer is disposed in the first opening. The first encapsulation layer is disposed in both the display area and the non-display area. At least a portion of the first encapsulation layer is disposed on the light emitting element. The partition wall is disposed on the first encapsulation layer in the display area. The partition wall includes a second opening overlapping the first opening in the view. The light control pattern layer is disposed in the second opening. The bank pattern layer is disposed in the non-display area. The bank pattern layer and the partition wall at least partially bound a third opening. The step difference compensation pattern layer is disposed in the third opening. The partition wall and the bank pattern layer are disposed in a same layer as one another. In the direction, a difference in height between the partition wall and the light control pattern layer is a first step difference. In the direction, a difference in height between the bank pattern layer and the step difference compensation pattern layer is a second step difference. The first step difference is smaller than the second step difference.

In an embodiment, the first step difference may be greater than 0 μm and less than or equal to about 1.5 μm.

In an embodiment, the second step difference may be in a range of about 1.5 μm to about 3 μm.

In an embodiment, in the direction, a height of the bank pattern layer may be in a range of about 8 μm to about 20 μm.

In an embodiment, the bank pattern layer may be disposed further from the display area than the partition wall.

In an embodiment, the bank pattern layer may include a same material as the partition wall.

In an embodiment, in the view, the bank pattern layer may be spaced apart from the partition wall, and in the view, the bank pattern layer may circumscribe the partition wall.

In an embodiment, in the direction, a height of the step difference compensation pattern layer may be smaller than a height of the bank pattern layer.

In an embodiment, in the direction, a height of the step difference compensation pattern layer may be in a range of about 5 μm to about 9 μm.

In an embodiment, the step difference compensation pattern layer and the light control pattern layer may be in a same layer as one another.

In an embodiment, the light control pattern layer may include a first light control pattern layer including a first quantum dot, a second light control pattern layer including a second quantum dot, and a third light control pattern layer including a light scattering particle. The first quantum dot may convert incident light into light in a red wavelength band. The second quantum dot may convert incident light into light in a green wavelength band. The light scattering particle may include titanium oxide. The step difference compensation pattern layer may include a same material as at least one of the first light control pattern layer, the second light control pattern layer, and the third light control pattern layer.

According to an aspect, a display device includes a display area, a non-display area, a light emitting element, a pixel defining layer, a partition wall, a light control pattern layer, a bank pattern layer, and a step difference compensation pattern layer. The display area includes pixels. A pixel among the pixels includes a first sub-pixel area, a second sub-pixel area, and a third sub-pixel area. The non-display area is outside the display area in a view in a direction. The light emitting element is disposed in at least one of the first sub-pixel area, the second sub-pixel area, and the third sub-pixel area. The light emitting element includes a first electrode, a light emitting layer disposed on the first electrode, and a second electrode disposed on the light emitting layer. The pixel defining layer includes a first opening exposing the first electrode. The partition wall is disposed in the display area. The partition wall includes a second opening overlapping the first opening in the direction. The light control pattern layer is disposed in the second opening. The bank pattern layer is disposed in the non-display area. The bank pattern layer and the partition wall at least partially bound a third opening. The step difference compensation pattern layer is disposed in the third opening. The partition wall and the bank pattern layer are disposed in a same layer as one another. The light control pattern layer includes: a first light control pattern layer disposed in the first sub-pixel area; a second light control pattern layer disposed in the second sub-pixel area; and a third light control pattern layer disposed in the third sub-pixel area. In the direction, a difference in height between the partition wall and the light control pattern layer is a first step difference. In the direction, a difference in height between the bank pattern layer and the step difference compensation pattern layer is a second step difference. The second step difference is in a range of about 1.5 μm to about 3 μm.

In an embodiment, the first step difference may be smaller than the second step difference.

In an embodiment, in the direction, a height of the bank pattern layer may be in a range of about 8 μm to about 20 μm.

In an embodiment, the bank pattern layer may include a same material as the partition wall. The bank pattern layer may include an organic material.

In an embodiment, in the view, the bank pattern layer may be spaced apart from the partition wall. In the view, the bank pattern layer may be disposed further from the display area than the partition wall. In the view, the bank pattern layer may circumscribe the partition wall.

In an embodiment, the first light control pattern layer may include a first quantum dot that coverts incident light into light in a red wavelength band. The second light control pattern layer may include a second quantum dot that converts incident light into light in a green wavelength band. The third light control pattern layer may include titanium oxide. The step difference compensation pattern layer may include at least one of the first quantum dot, the second quantum dot, and the titanium oxide.

According to an aspect, a display device includes a display area, a non-display area, light emitting elements, a pixel defining layer, a partition wall, light control pattern layers, a first bank pattern layer, a first step difference compensation pattern layer, a second bank pattern layer, and a second step difference compensation pattern layer. The display area includes sub-pixel areas. The non-display area is outside of the display area. The light emitting elements are respectively disposed in the sub-pixel areas. Each light emitting element among the light emitting elements includes a first electrode, a light emitting layer disposed on the first electrode, and a second electrode disposed on the light emitting layer. The pixel defining layer includes first openings respectively exposing the first electrodes. The partition wall is disposed in the display area. The partition wall includes second openings respectively overlapping the first openings in the direction. The light control pattern layers are respectively disposed in the second openings. The first bank pattern layer is disposed in the non-display area. The first bank pattern layer at least partially bounds a third opening and circumscribes the partition wall in the view. The first step difference compensation pattern layer is disposed in the third opening. The second bank pattern layer is disposed in the non-display area, is disposed adjacent to the first bank pattern layer, and is disposed further from the display area than the first bank pattern layer. The second bank pattern layer at least partially bounds a fourth opening. The second step difference compensation pattern layer is disposed in the fourth opening. Each of the partition wall, the first bank pattern layer, and the second bank pattern layer is disposed in a same layer as one another. The light control pattern layer includes a first light control pattern layer disposed in a first sub-pixel area among the sub-pixel areas, a second light control pattern layer disposed in a second sub-pixel area among the sub-pixel areas, and a third light control pattern layer disposed in a third sub-pixel area among the sub-pixel areas. In the direction, a difference in height between the partition wall and at least one of the light control pattern layers is a first step difference. In the direction, a difference in height between the first bank pattern layer and the first step difference compensation pattern layer is a second step difference. The second step difference is in a range of about 1.5 μm to about 3 μm.

In an embodiment, in the view, the second bank pattern layer may be spaced apart from the first bank pattern layer and may circumscribe the first bank pattern layer. The first light control pattern layer may include a first quantum dot that coverts incident light into light in a red wavelength band. The second light control pattern layer may include a second quantum dot that coverts incident light into light in a green wavelength band. The third light control pattern layer may include titanium oxide. Both the first step difference compensation pattern layer and the second step difference compensation pattern layer may include at least one of the first quantum dot, the second quantum dot, and the titanium oxide.

In an embodiment, in the direction, a difference in height between the second bank pattern layer and the second step difference compensation pattern layer may be a third step difference. The third step difference may be greater than the second step difference.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 is a schematic perspective view illustrating a display device in accordance with an embodiment.

FIG. 2 is a schematic sectional view illustrating a display device in accordance with an embodiment.

FIG. 3 is a schematic sectional view taken along sectional line I-I′ shown in FIG. 1 in accordance with an embodiment.

FIG. 4 is a schematic sectional view illustrating a light control pattern layer disposed in a sub-pixel area in accordance with an embodiment.

FIG. 5 is a schematic sectional view taken along sectional line II-II′ shown in FIG. 1 in accordance with an embodiment.

FIG. 6 is a schematic sectional view taken along sectional line II-II′ shown in FIG. 1 in accordance with an embodiment.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. In a case that an embodiment may be implemented differently, a specific process order may be performed differently from the described order. For example, two consecutively described processes may be performed substantially at the same time or performed in an order opposite the described order. Also, like reference numerals and/or reference characters denote like elements.

In a case that an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. However, in a case that an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the terms “substantially,” if used herein, and unless otherwise specified, may mean within 5% of a referenced value. For example, substantially perpendicular may mean within ±5% of being parallel. The terms “about” and “approximately,” if used herein, and unless otherwise specified, may mean within one or more standard deviations, or within ±30%, ±20%, ±10%, or ±5% of a stated value. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4. Furthermore, the expression “being the same” may mean “being substantially the same.” For instance, the expression “being the same” may include a range that can be tolerated by those skilled in the art. Other expressions may also be expressions from which “substantially” has been omitted.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described with reference to the accompanying drawings.

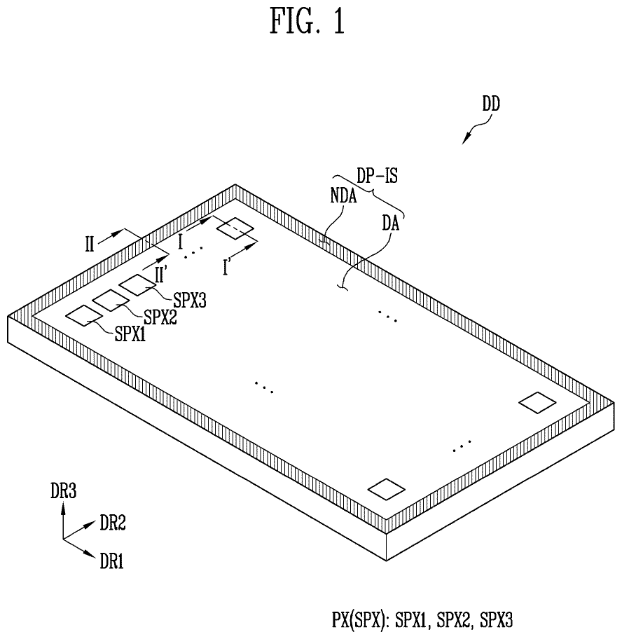

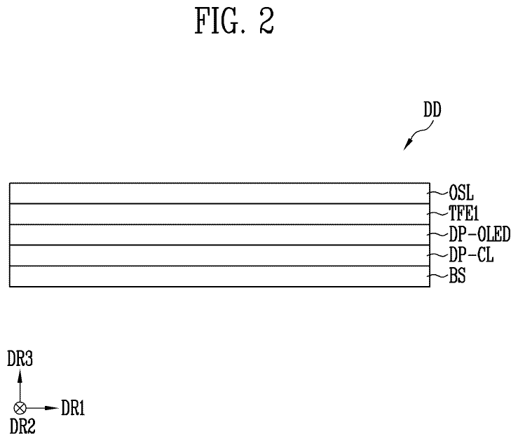

FIG. 1 is a schematic perspective view illustrating a display device in accordance with an embodiment. FIG. 2 is a schematic sectional view illustrating the display device in accordance with an embodiment.

Referring to FIGS. 1 and 2, the display device DD may display an image through a display surface DP-IS. The display surface DP-IS may be parallel (or substantially parallel) to a plane defined by a first direction DR1 and a second direction DR2.

Hereinafter, an upper direction may be defined as a direction normal to the display surface DP-IS (e.g., a direction normal to a plane on which a light control layer OSL may be disposed). For example, the upper direction may be a third direction DR3, which may be perpendicular to both the first direction DR1 and the second direction DR2.

A front surface (or top surface) and a rear surface (or bottom surface) of each of various layers or structures, which are described herein, may be distinguished (or spaced apart) from each other by (or in) the third direction DR3.

The display device DD may include a display area DA and a non-display area NDA. The non-display area NDA may mean an area other than the display area DA. The non-display area NDA may be outside the display area in a view in the third direction DR3. Hereinafter, unless otherwise specified, a view in the third direction DR3 will be referred to as a plan view. In some implementations, the non-display area NDA may surround (or circumscribe) at least a portion of the display area DA in a plan view. As used herein, the term “circumscribe” is not limited to a first feature forming a circle around a second feature, and as such, may include the first feature forming any suitable two-dimensional geometric figure around the second feature in a plan view. A first feature being “around,” “surrounding,” or “circumscribing” a second feature may (unless otherwise specified) include an inner boundary of the first feature touching one or more points of an outer boundary of the second feature, or the inner boundary of the first feature may be spaced apart from the outer boundary of the second feature. A first feature being “around,” “surrounding,” or “circumscribing” a second feature may include (unless otherwise specified) the first feature completely or partially being around, surrounding, or circumscribing the second feature in a plan view. The non-display area NDA may be defined (or extend) along one or more edges of the display surface DP-IS.

The display area DA may mean an area in which pixels PX are disposed. The non-display area NDA may mean an area in which the pixels PX are not disposed. A driving circuit, lines, and pads, which may be electrically connected to the pixels PX of the display area DA, may be disposed in the non-display area NDA.

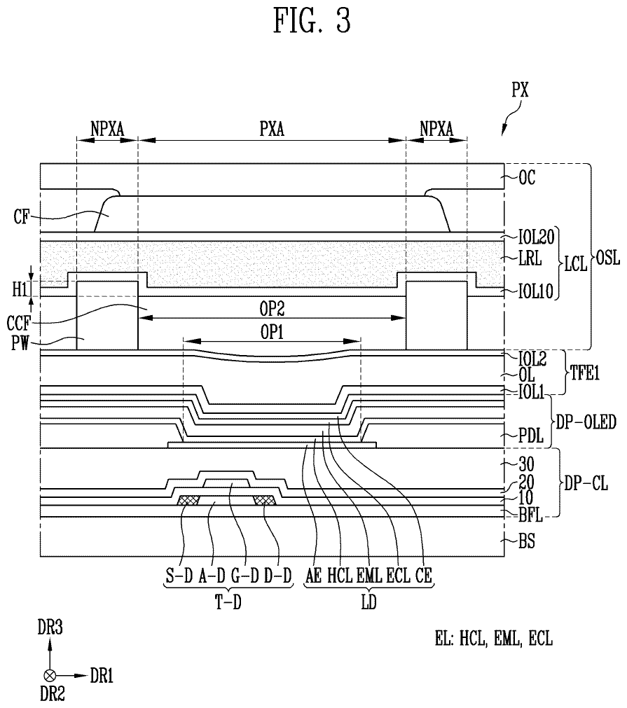

Each pixel PX may include a light emitting element LD (see FIG. 3). In some embodiments, the display device DD may include at least one of an inorganic light emitting display panel including an inorganic light emitting element and an organic light emitting display panel including an organic light emitting element, but embodiments are not limited to these example types of display devices. For convenience, an embodiment in which the light emitting element LD includes an organic light emitting element will be mainly described.

In some embodiments, a pixel PX (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may form one (or a) unit pixel capable of emitting lights of various colors. In FIG. 1, it is exemplified that each pixel PX includes three sub-pixels SPX, e.g., the first sub-pixel SPX1, the second sub-pixel SPX2, and the third sub-pixel SPX3. However, embodiments are not limited to the above-noted number of sub-pixels SPX per pixel PX.

In some embodiments, the pixels PX (or sub-pixels SPX) may be arranged according to a stripe arrangement structure, a Pentile™ arrangement structure, a matrix arrangement structure, and/or the like. However, embodiments are not limited to these example pixel (or sub-pixel) arrangements.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm. However, embodiments are not limited to these example ranges.

Although FIG. 1 illustrates the display device DD having a planar display surface DP-IS, embodiments are not limited to this example. The display device DD may include a curved display surface or a three-dimensional display surface. The three-dimensional display surface may include multiple display areas having corresponding display surfaces extending along one or more similar and/or different directions. The display device DD may be at least one of a rollable display device, a foldable display device, a bendable display device, a flexible display device, a twistable display device, and a slidable display device. The display device DD may have flexible properties and may be at least one of foldable, bendable, flexible, twistable, and rollable.

As shown in FIG. 2, the display device DD may include a base substrate BS, a circuit element layer DP-CL disposed on the base substrate BS, a display element layer DP-OLED disposed on the circuit element layer DP-CL, a first encapsulation layer TFE1 disposed on the display element layer DP-OLED, and the light control layer OSL disposed on the first encapsulation layer TFE1.

The base substrate BS may include a at least one of glass substrate, a plastic substrate, and an organic/inorganic composite substrate. The circuit element layer DP-CL may include a driving circuit and/or signal lines of the pixels PX. The display element layer DP-OLED may include the light emitting element LD (see FIG. 3). In some implementations, each pixel PX may include one or more respective light emitting elements LD to form the pixel PX and/or sub-pixel SPX. The first encapsulation layer TFE1 may include at least one inorganic layer sealing the light emitting element LD. The light control layer OSL may change an optical property of incident light generated in (or by) the light emitting element LD. Hereinafter, the display device DD will be described in more detail with reference to FIGS. 3, 4, and 5.

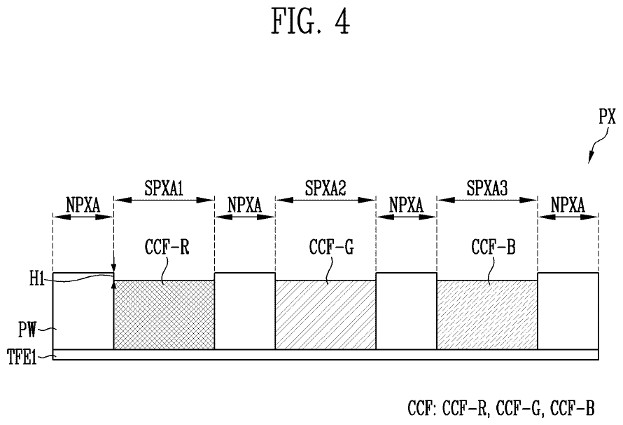

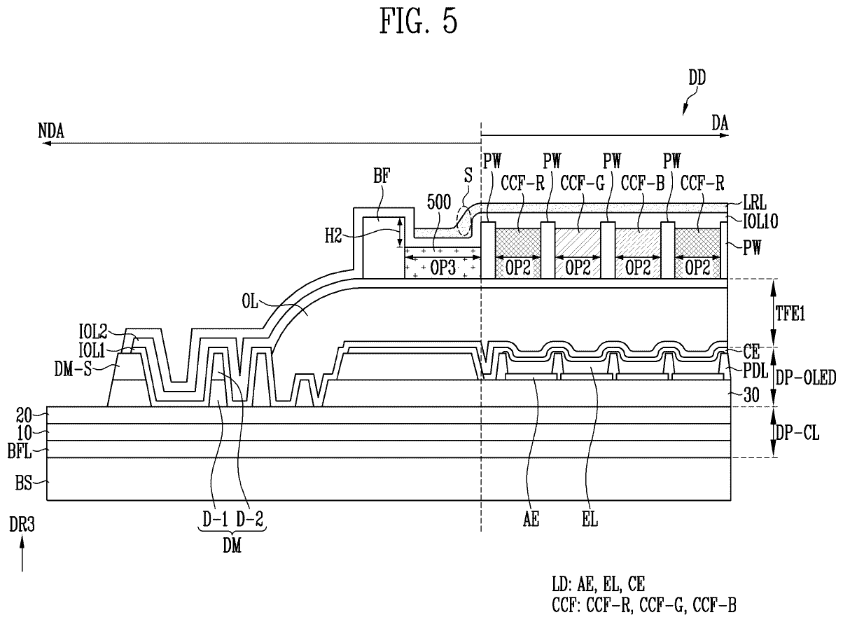

FIG. 3 is a schematic sectional view taken along sectional line I-I′ shown in FIG. 1 in accordance with an embodiment. FIG. 4 is a schematic sectional view illustrating a light control pattern layer disposed in a sub-pixel area in accordance with an embodiment. FIG. 5 is a schematic sectional view taken along sectional line II-II′ shown in FIG. 1 in accordance with an embodiment. For instance, FIG. 3 schematically illustrates a section corresponding to a pixel PX (e.g., a section of the display area DA), FIG. 4 schematically illustrates a light control pattern layer CCF corresponding to a first sub-pixel SPX1, a second sub-pixel SPX2, and a third sub-pixel SPX3 in the pixel PX, and FIG. 5 schematically illustrates a section corresponding to a portion of the display area DA and the non-display area NDA. As compared with FIG. 3, components except the light control pattern layer CCF are briefly illustrated or omitted in FIG. 4, and a partial configuration of a first encapsulation layer TFE1, a color filter CF, and a protective layer OC are omitted in FIG. 5.

Referring to FIGS. 3 and 4, the display area DA may include a pixel area PXA and a peripheral area NPXA. The pixel area PXA may be disposed to correspond to multiple pixels PX (or sub-pixels SPX, such as the first, second, and third sub-pixels SPX1, SPX2, and SPX3) such as shown in FIG. 1. For example, the pixel area PXA may overlap an area in which the pixels PX (or sub-pixels SPX, e.g., the first, second, and third sub-pixels SPX1, SPX2, and SPX3) shown in FIG. 1 emit light in a plan view. For example, the pixel area PXA may be defined to correspond to a second opening OP2 (or to overlap the second opening OP2 in a plan view).

The peripheral area NPXA may set (or partition) a boundary of multiple pixel areas PXA, and may prevent (or at least mitigate) color mixture between the pixel areas PXA. For example, the peripheral area NPXA may be defined as an area in which a partition wall PW is disposed (or an area overlapping the partition wall PW in a plan view).

The pixel areas PXA may include a first sub-pixel area SPXA1 providing light of a first color (e.g., light in a red wavelength band), a second sub-pixel area SPXA2 providing light of a second color (e.g., light in a green wavelength band), and a third sub-pixel area SPXA3 providing light of a third color (e.g., light in a blue wavelength band). Embodiments are not limited to a combination of ted, green, and blue colors, and additional and/or alternative color combinations may be used. Hereinafter, for convenience, sectional structures of the first sub-pixel area SPXA1, the second sub-pixel area SPXA2, and the third sub-pixel area SPXA3 are substantially same, and hence the pixel area PXA shown in FIG. 3 is described as the first sub-pixel area SPXA1 providing light in the red wavelength band.

Differences between the first, second, and third sub-pixel areas SPXA1, SPXA2, and SPXA3 are specified below, and components except specified components may be identical (or substantially identical) to one another in the first, second, and third sub-pixel areas SPXA1, SPXA2, and SPXA3.

Areas of the first sub-pixel area SPXA1, the second sub-pixel area SPXA2, and the third sub-pixel area SPXA3 may be equivalent or different from one another, and are not limited to the illustrated configurations.

In FIG. 3, a section of the pixel PX corresponding to a driving transistor T-D and a light emitting element LD is exemplarily illustrated. The display device DD may include multiple insulating layers, multiple semiconductor patterns, multiple conductive patterns, multiple signal lines, and/or the like. Insulating layers, semiconductor layers, and conductive layers may be formed through one or more processes, such as coating, deposition, patterned, and/or the like processes. The insulating layers, semiconductor layers, and conductive layers may be selectively patterned through at least one of a photolithography process and an etching process. Semiconductor patterns, conductive patterns, signal lines, and/or the like, which are included in a circuit element layer DP-CL and a display element layer DP-OLED, may be formed through one or more deposition processes, patterning processes, and/or the like.

The circuit element layer DP-CL may include a buffer layer BFL, a first insulating layer 10, a second insulating layer 20, and a third insulating layer 30. In some embodiments, the buffer layer BFL, the first insulating layer 10, and the second insulating layer 20 may be inorganic layers, and the third insulating layer 30 may be an organic layer. For example, the buffer layer BFL, the first insulating layer 10, and the second insulating layer 20 may include an inorganic material, and the third insulating layer 30 may include an organic material. However, embodiments are not limited to this example. For example, the buffer layer BFL, the first insulating layer 10, the second insulating layer 20, and the third insulating layer 30 may all be inorganic layers.

In some embodiments, the organic material may include at least one of acryl resin, epoxy resin, phenol resin, polyamide resin, polyimide resin, and benzocyclobutene (BCB). Embodiments are not limited to these example materials.

In some embodiments, the inorganic material may include at least one of silicon nitride (SiNₓ), silicon oxide (SiOₓ), silicon oxynitride (SiOₓN_{y}), and aluminum oxide (AlOₓ). Embodiments are not limited to these example materials.

In FIG. 3, an arrangement relationship of an active region A-D, a source S-D, a drain D-D, and a gate G-D, which may constitute (or form) the driving transistor T-D, is exemplarily illustrated. The active region A-D, the source S-D, and the drain D-D may be areas divided according to a doping concentration and/or conductivity of a semiconductor pattern.

The display element layer DP-OLED may include a pixel defining layer PDL and the light emitting element LD.

The pixel defining layer PDL may include a first opening OP1. The pixel defining layer PDL may define (or at least partially bound) the first opening OP1. For example, the pixel defining layer PDL may define the first opening OP1, which may expose at least a portion of at least one component (e.g., a first electrode AE) of the light emitting element LD. For example, the pixel defining layer PDL may define the first opening OP1 in which at least a portion of at least one component (e.g., a light emitting layer EML) of the light emitting element LD is disposed.

In some embodiments, the pixel defining layer PDL may be an organic layer. In some embodiments, the pixel defining layer PDL may include an organic material. However, embodiments are not limited to these examples. In some embodiments, the pixel defining layer PDL may be an inorganic layer. In some embodiments, the pixel defining layer PDL may include an inorganic material. In some embodiments, the pixel defining layer PDL may include one or more organic layers and one or more inorganic layers. In some embodiments, the pixel defining layer PDL may include one or more organic materials and one or more inorganic materials.

The pixel defining layer PDL may include a black coloring agent or a light blocking material. For example, the pixel defining layer PDL may include a black dye (or black pigment) mixed in a base resin. In some embodiments, the black coloring agent may include carbon black or include a metal, such as chromium or an oxide of chromium.

The light emitting element LD may generate source light. The light emitting element LD may include the first electrode AE, a second electrode CE, and a light emitting structure EL disposed between the first electrode AE and the second electrode CE.

The first electrode AE may be disposed on the third insulating layer 30. The first electrode AE may be electrically connected directly or indirectly to the driving transistor T-D. In FIG. 3, an electrical connection structure between the first electrode AE and the driving transistor T-D is not shown. At least a portion of the first electrode AE may be exposed by the first opening OP1.

In some embodiments, the first electrode AE may be an anode electrode of the light emitting element LD. However, embodiments are not limited to this example. In some embodiments, the first electrode AE may be a cathode electrode of the light emitting element LD.

The light emitting structure EL may include a hole control layer HCL, the light emitting layer EML, and an electron control layer ECL. The light emitting structure EL may be integrally and commonly disposed in the pixel area PXA and the peripheral area NPXA. However, embodiments are not limited to this example.

The hole control layer HCL, the light emitting layer EML, and the electron control layer ECL may be commonly disposed in the pixel area PXA and the peripheral area NPXA. The hole control layer HCL, the light emitting layer EML, and the electron control layer ECL may be commonly disposed in the pixel area PXA. Light emitting layers EML of the pixel areas PXA may have an integrated shape. A light emitting layer EML of the first sub-pixel area SPXA1, a light emitting layer EML of the second sub-pixel area SPXA2, and a light emitting layer EML of the third sub-pixel area SPXA3 may have an integrated shape, and the light emitting layer EML may generate source light of a same color regardless of a position of the light emitting layer EML relative to the first sub-pixel area SPXA1 area, the second sub-pixel area SPXA2, and the third sub-pixel area SPXA3. However, embodiments are not limited to this example. The light emitting structure EL may not be integrally formed, and may be respectively disposed in the first openings OP1 of each of the first sub-pixel area SPXA1, the second sub-pixel area SPXA2, and the third sub-pixel area SPXA3.

The hole control layer HCL may include a hole transport layer, and may further include a hole injection layer. The light emitting layer EML may generate, as the source light, light in a blue wavelength band. However, embodiments are not limited to this example.

Hereinafter, for convenience, an embodiment in which the light emitting layer EML generates, as the source light, the light in the blue wavelength band will be mainly described. The electron control layer ECL may include an electron transport layer, and may further include an electron injection layer.

The second electrode CE may be disposed on the electron control layer ECL. The second electrode CE may be commonly disposed in the pixel areas PXA. The second electrode CE may be integrally disposed throughout (or substantially throughout) the pixel area PXA and the peripheral area NPXA. The pixel areas PXA may include the second electrode CE having an integrated shape.

In some embodiments, the second electrode CE may be the cathode electrode of the light emitting element LD. However, embodiments are not limited to this example. In some embodiments, the second electrode CE may be the anode electrode of the light emitting element LD.

The first encapsulation layer TFE1 sealing the light emitting element LD may be disposed over the second electrode CE, e.g., the light emitting element LD may overlap the second electrode CE in a plan view. The first encapsulation layer TFE1 may be disposed over the light emitting elements LD throughout the display area DA and may be disposed over the non-display area NDA.

The first encapsulation layer TFE1 may include at least one inorganic layer. For example, the first encapsulation layer TFE1 may have a multi-layer structure in which an inorganic layer and an organic layer are repeated. For example, the first encapsulation layer TFE1 may include a first encapsulation inorganic layer IOL1, an encapsulation organic layer OL disposed on the first encapsulation inorganic layer IOL1, and a second encapsulation inorganic layer IOL2 disposed on the encapsulation organic layer OL. The first and second encapsulation inorganic layers IOL1 and IOL2 may protect (or mitigate exposure of) the light emitting element LD from (or to) external moisture, and the encapsulation organic layer OL may prevent (or at least mitigate) a defect that the light emitting element LD is damaged by a foreign matter or untended impact introduced during a manufacturing process.

The light control layer OSL may be disposed on the first encapsulation layer TFE1. The light control layer OSL may include the partition wall PW, the light control pattern layer CCF, a refractive index control layer LCL, the color filter CF, and the protective layer OC.

The partition wall PW may include a black coloring agent to block light. The partition wall PW may include a black dye (or black pigment) mixed in a base resin. In some embodiments, the black coloring agent may include carbon black or include a metal, such as chromium or an oxide of chromium. In some embodiments, the partition wall PW may be an organic layer including an organic material.

The partition wall PW may include the second opening OP2 corresponding to the first opening OP1. For example, the partition wall PW may include the second opening OP2 overlapping the first opening OP1 in a plan view. The second opening OP2 may overlap the first electrode AE in a plan view. In some embodiments, an area (e.g., a cross-sectional area in a plane perpendicular to the third direction DR3) of the second opening OP2 may be greater than a corresponding area of the first opening OP1. However, embodiments are not limited to this example.

The light control pattern layer CCF may be disposed in the second opening OP2. The light control pattern layer CCF may improve the luminance of output light as compared with incident light. The light control pattern layer CCF may change an optical property of the source light emitted from the light emitting element LD. The light control pattern layer CCF may include a first light control pattern layer CCF-R disposed in the first sub-pixel area SPXA1, a second light control pattern layer CCF-G disposed in the second sub-pixel area SPXA2, and a third light control pattern layer CCF-B disposed in the third sub-pixel area SPXA3. The first light control pattern layer CCF-R and the second light control pattern layer CCF-G may correspond to a color conversion pattern layer capable of converting a color of the source light. For example, the first light control pattern layer CCF-R and the second light control pattern layer CCF-G may convert a wavelength of the source light. For example, the first light control pattern layer CCF-R may convert the source light in a blue wavelength band into light in a red wavelength band, and the second light control pattern layer CCF-G may convert the source light in the blue wavelength band into light in a green wavelength band.

The third light control pattern layer CCF-B may be a transmission pattern layer. The third light control pattern layer CCF-B may include a light scattering particle, thereby scattering and outputting the source light in the blue wavelength band.

The color conversion pattern layer (e.g., the first light control pattern layer CCF-R and the second light control pattern layer CCF-G) may include a base resin and at least one of quantum dots, quantum rods, and phosphors mixed (or dispersed) in the base resin. For convenience, an example in which quantum dots are used will mainly be described. For example, the color conversion pattern layer may include the quantum dots, and may be defined as a quantum dot pattern layer.

The base resin may be a medium in which the quantum dots are dispersed, and may be made of (or include) one or more resin compositions, which can be generally designated as a binder. However, embodiments are not limited to this example. In some embodiments, any medium capable of dispersing and disposing the quantum dots may be designated as the base resin regardless of a name of the medium, another and/or additional function, a material constituting the medium, and/or the like. The base resin may be a polymer resin. For example, the base resin may be at least one of an acryl-based resin, a urethane-based resin, a silicon-based resin, an epoxy-based resin, and the like. The base resin may be a transparent resin.

The first light control pattern layer CCF-R and the second light control pattern layer CCF-G may include different quantum dots from one another. For example, the first light control pattern layer CCF-R may be a layer formed by curing a first ink including a first base resin and a first quantum dot, and the second light control pattern layer CCF-G may be a layer formed by curing a second ink including a second base resin and a second quantum dot. The first quantum dot and the second quantum dot may be different quantum dots from one another.

The quantum dots may be particles that convert a wavelength of light. For example, the first quantum dot may convert incident light into light in a red wavelength band. For example, the second quantum dot may convert incident light into light in a green wavelength band.

The quantum dots may correspond to a material having a crystalline structure of a few nanometers size, may be configured with about hundreds or thousands of atoms, and may exhibit a quantum confinement effect that an energy band gap is increased due to a small size. In a case that light of a wavelength having energy higher than the energy band gap is incident with the quantum dots, the quantum dots may be in an excited state by absorbing the light, and may drop to a ground state and emit light of a specific (or determined) wavelength. The energy of the emitted light may have a value corresponding to the energy band gap. The size, composition, and/or the like of the quantum dots may be adjusted, thereby adjusting light emission characteristics caused by the quantum confinement effect.

The quantum dots may include one or more materials, such as at least one of a Group II-VI compound, a Group I-III-VI compound, a Group III-V compound, a Group IV-VI compound, a Group IV element, and a Group IV compound.

The quantum dots may have a core/shell structure including a core and a shell surrounding the core. The quantum dots may have a core/shell structure in which one quantum dot surrounds another quantum dot. An interface between the core and the shell may have a concentration gradient in which the concentration of an element existing in the shell becomes lower as the concentration gradient approaches the core.

The quantum dots may be particles having a size on the order of a nanometer scale. The quantum dots may have a full width at half maximum (FWHM) of a light emitting wavelength spectrum in a range of about 45 nm or less, such as about 40 nm or less, for instance, about 30 nm or less, and may improve color purity and/or color reproducibility in these ranges. Light emitted through the quantum dots may be emitted in all directions, and a light viewing angle may be improved.

In some embodiments, a form of the quantum dots may be a form generally used in the art and is not limited. In some implementations, forms, such as spherical, pyramidal, multi-arm-shaped, and/or cubic nanoparticles, nanotubes, nanowires, nanofibers, and/or nanoplate-shaped particles may be used. The quantum dot may adjust the color of emitted light according to the particle size. The quantum dot may emit light of various colors, such as light in a red wavelength band, light in a green wavelength band, and/or light in a blue wavelength band.

The transmission pattern layer (e.g., the third light control pattern layer CCF-B) may not include a wavelength conversion material (e.g., a quantum dot). The transmission pattern layer may include a base resin and a light scattering particle. In some embodiments, the third light control pattern layer CCF-B may be a layer formed by curing a third ink including a third base resin and a light scattering particle. For example, the light scattering particle may be a titanium oxide (TiOₓ) (e.g., TiO₂) or silica-based nano particle.

In some embodiments, like the above-described transmission pattern layer, the color conversion pattern layer may further include a light scattering particle mixed in the base resin.

In some embodiments, the light control pattern layer CCF may be formed through an inkjet process. For example, a liquid composition may be provided in the second opening OP2. For example, the first ink may be provided in a second opening OP2 of the first sub-pixel area SPXA1. For example, the second ink may be provided in a second opening OP2 of the second sub-pixel area SPXA2. For example, the third ink may be provided in a second opening OP2 of the third sub-pixel area SPXA3.

A volume of a composition of the light control pattern layer CCF, which may be polymerized through a thermosetting process and/or a photocuring process, may be decreased after curing. A step difference may occur between a top surface of the partition wall PW and a top surface of the light control pattern layer CCF. For example, the partition wall PW may have a height higher (or larger) than a height of the light control pattern layer CCF, and the partition wall PW and the light control pattern layer CCF may have a height difference corresponding to a first step difference H1. Hereinafter, a height and a step difference may be defined in the third direction DR3 unless otherwise specified. In some embodiments, the partition wall PW may have a height in a range of about 8 μm to about 20 μm. In some embodiments, the partition wall PW may have a height in a range of about 8 μm to about 15 μm. The first step difference H1 may be greater than 0 μm and less than or equal to about 1.5 μm.

The refractive index control layer LCL may be disposed on the partition wall PW and the light control pattern layer CCF. The refractive index control layer LCL may be disposed throughout (or substantially throughout) the pixel area PXA and the peripheral area NPXA. The refractive index control layer LCL may include a first capping layer IOL10, a low refractive layer LRL, and a second capping layer IOL20. The first and second capping layers ILO10 and IOL20 may protect the light control pattern layer CCF from external moisture (or at least mitigate the intrusion of external moisture), and the low refractive layer LRL may reflect, toward the light control pattern layer CCF, a portion of light emitted in a direction toward the color filter CF from the light emitting element LD.

The low refractive layer LRL may have a relatively low refractive index as compared with the components of the light control pattern layer CCF. For example, the relatively low refractive layer LRL may have a refractive index in a range of about 1.1 to about 1.5. However, embodiments are not limited to this example range.

The low refractive layer LRL may re-reflect, toward the light control pattern layer CCF, a portion of light advancing toward the color filter CR and being transmitted through the light control pattern layer CCF to be recycled, thereby improving light use (or emitting) efficiency and wavelength conversion efficiency.

In some embodiments, the low refractive layer LRL may include a hollow silica particle of which at least a portion of the silica particle is empty. However, embodiments are not limited to this example. In some embodiments, the low refractive layer LRL may include at least one of a zinc oxide (ZnO) particle, a titanium dioxide (TiO₂) particle, a silica particle of which the inside is not empty, a nano silicate particle, and a porogen particle. Embodiments, however, are not limited to these example materials.

Each of the first capping layer IOL10 and the second capping layer IOL20 may include at least one of silicon nitride (SiNₓ), silicon oxide (SiOₓ), silicon oxynitride (SiOₓN_{y}), and aluminum oxide (AlOₓ). Embodiments, however, are not limited to these example materials.

The color filter CF may be disposed on the refractive index control layer LCL. The color filter CF may include a first color filter disposed in the first sub-pixel area SPXA1, a second color filter disposed in the second sub-pixel area SPXA2, and a third color filter disposed in the third sub-pixel area SPXA3. The color filter CF may allow light in a specific, determined, or selected wavelength band to be transmitted through the color filter CF, and may block light except the light in the corresponding wavelength band. For example, the first color filter may allow light in a red wavelength band to be transmitted through the first color filter, and may block light in a green wavelength band and light in a blue wavelength band. The second color filter may allow light in the green wavelength band to be transmitted through the second color filter, and may block light in the red wavelength band and light in the blue wavelength band. The third color filter may allow light in the blue wavelength band to be transmitted through the third color filter, and may block light in the red wavelength band and light in the green wavelength band.

The color filter CF may include a base resin and a dye (or pigment) dispersed in the base resin. The base resin may be a medium in which the dye is dispersed, and may be made of one or more resin compositions, which may be generally designated as a binder. The first color filter may include a red colorant, such as at least one of a red dye and a red pigment. The second color filter may include a green colorant, such as at least one of a green dye and a green pigment. The third color filter may include a blue colorant, such as at least one of a blue dye and a blue pigment.

The protective layer OC may be disposed over the color filter CF, e.g., the protective layer OC may overlap the color filter CF in the third direction DR3. The protective layer OC may be an organic layer that protects the color filter CF. The protective layer OC may include at least one of a photocurable organic material and a thermosetting organic material. However, embodiments are not limited to this example. The protective layer OC may be an inorganic layer.

Referring to FIG. 5, the display device DD may include a dam line DM, which may be disposed in a region outside of the pixel defining layer PDL (e.g., disposed at or adjacent to a side of the pixel defining layer PDL in a direction toward the non-display area NDA from the display area DA) and may overlap the non-display area NDA. Although three dam lines DM are illustrated as an example in FIG. 5, the number of dam lines DM is not limited to the illustrated example. In an embodiment, the dam line DM may be omitted, or a different number of dam lines DM may be utilized.

The dam line DM may control spreading of a liquid composition such that the liquid composition does not get out of (or flow beyond) the base substrate BS during a manufacturing process of the encapsulation organic layer OL of the first encapsulation layer TFE1. The dam line DM may include a first layer D-1 and a second layer D-2 disposed on the first layer D-1. However, embodiments are not limited to this example. In some embodiments, the dam line DM may include only the first layer D-1. The first layer D-1 may be formed through a same manufacturing process (including, for instance, a photo phase and a development phase) as the third insulating layer 30, and the second layer D-2 may be formed through a same manufacturing process (e.g., including a photo phase and a development phase) as the pixel defining layer PDL.

A sub-dam line DM-S may be disposed outside of the dam line DM, e.g., the sub-dam line DM-S may be disposed further from the display area DA than the dam line DM. The first encapsulation inorganic layer IOL1 and the second encapsulation inorganic layer IOL2 of the first encapsulation layer TFE1 may overlap the dam line DM in, for instance, the third direction DR3. The first encapsulation inorganic layer IOL1 and the second encapsulation inorganic layer IOL2 of the first encapsulation layer TFE1 may overlap at least a portion of the sub-dam line DM-S in, for instance, the third direction DR3.

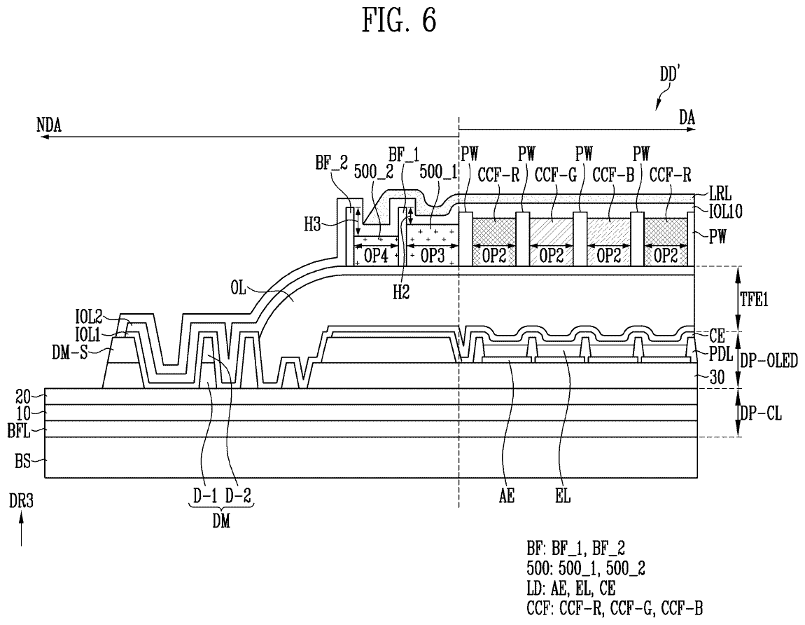

The display device DD may include a bank pattern layer BF that may be disposed at an outside of the partition wall PW (e.g., at a side of the partition wall PW in a direction toward the non-display area NDA from the display area DA) and may overlap the non-display area NDA. Although one bank pattern layer BF is illustrated as an example in FIG. 5, a number of bank pattern layers BF is not limited to the depicted example. An embodiment in which multiple bank pattern layers BF are formed will be described later with reference to FIG. 6.

The bank pattern layer BF may be disposed in the non-display area NDA. The bank pattern layer BF may overlap the non-display area NDA in a plan view. In some embodiments, the bank pattern layer BF may not overlap the light emitting structure EL (or the light emitting layer EML) in a plan view.

The bank pattern layer BF may be spaced apart from the partition wall PW at a distance to surround (or circumscribe) the partition wall PW in a plan view. The bank pattern layer BF along with the partition wall PW may define (or at least partially bound) a third opening OP3. For example, the bank pattern layer BF may be disposed closer to an edge of the display device DD than the partition wall PW. For instance, the bank pattern layer BF may be disposed further from the display area DA than the partition wall PW. The bank pattern layer BF may be spaced part from the partition wall PW to define the third opening OP3. The third opening OP3 may be disposed closer to an edge of the display device DD than the second opening OP2, e.g., the third opening OP3 may be disposed further from the display area DA than the second opening OP2.

The bank pattern layer BF may be disposed on (or in) a same layer as the partition wall PW. The bank pattern layer BF may be formed through a same manufacturing process as the partition wall PW. The bank pattern layer BF may include a same material as the partition wall PW. For example, the bank pattern layer BF may include a black dye (or black pigment) mixed in a base resin. In some embodiments, the bank pattern layer BF may be an organic layer including an organic material.

In some embodiments, the bank pattern layer BF may have a same height as the partition wall PW. However, embodiments are not limited to this example. In some embodiments, the bank pattern layer BF may have a height in a range of about 8 μm to about 20 μm. In some embodiments, the bank pattern layer BF may have a height in a range of about 8 μm to about 15 μm.

A step difference compensation pattern layer 500 may be disposed inside the third opening OP3. The step difference compensation pattern layer 500 may be disposed on (or in) a same layer as the light control pattern layer CCF. The step difference compensation pattern layer 500 may include a same material as at least one of the light control pattern layers included in (or as part of) the light control pattern layer CCF.

For example, the step difference compensation pattern layer 500 may be formed through a same manufacturing process as the first light control pattern layer CCF-R, and may include a same material as the first light control pattern layer CCF-R. For example, the step difference compensation pattern layer 500 may include the first ink. The step difference compensation pattern layer 500 may include the first base resin and the first quantum dot.

For example, the step difference compensation pattern layer 500 may be formed through a same manufacturing process as the second light control pattern layer CCF-G, and may include a same material as the second light control pattern layer CCF-G. For example, the step difference compensation pattern layer 500 may include the second ink. The step difference compensation pattern layer 500 may include the second base resin and the second quantum dot.

For example, the step difference compensation pattern layer 500 may be formed through a same manufacturing process as the third light control pattern layer CCF-B, and may include a same material as the third light control pattern layer CCF-B. For example, the step difference compensation pattern layer 500 may include the third ink. The step difference compensation pattern layer 500 may include the third base resin and the light scattering particle.

The step difference compensation pattern layer 500 may fill (e.g., partially fill) the third opening OP3, thereby decreasing a step difference between an area overlapping the third opening OP3 in a plan view and the bank pattern layer BF. The step difference compensation pattern layer 500 may fill the third opening OP3 to have a height lower than a height of the bank pattern layer BF. In some embodiments, the height of the step difference compensation pattern layer 500 may be in a range of about 5 μm to about 9 μm. However, embodiments are not limited to this example range. The step difference compensation pattern layer 500 and the bank pattern layer BF may have a height difference corresponding to a second step difference H2.

The second step difference H2 may be greater than the first step difference H1. For example, the second step difference H2 may be greater than about 1.5 μm and less than or equal to about 3 μm. The step difference compensation pattern layer 500 and the bank pattern layer BF may have a height difference corresponding to the second step difference H2, and the low refractive layer LRL may be formed on the step difference compensation pattern layer 500 and the bank pattern layer BF.

In a case in which the low refractive layer LRL is formed through an inkjet printing process, the low refractive layer LRL may be formed beyond an outside of (or outer boundary of) the bank pattern layer BF due to material characteristics of the low refractive layer LRL and in a case that the second step difference H2 is about 1.5 μm or less. In a case that the low refractive layer LRL is formed beyond the outside of the bank pattern layer BF, the low refractive layer LRL may be excessively deposited on an outer side surface of the bank pattern layer BF relative to the display area DA. Lifting (or delamination) of the low refractive layer LRL may occur in a relatively high-temperature and relatively high-humidity condition (e.g., a temperature of about 85° C. or higher and a humidity of about 85% or higher), and the low refractive layer LRL may be damaged. Damage to the low refractive layer LRL may cause, at least in part, the display quality and light efficiency of the display device DD to deteriorate.

In a case that the second step difference H2 is greater than about 3 μm, the low refractive layer LRL may be excessively deposited on an outer side area S of the partition wall PW due to material characteristics of the low refractive layer LRL. Cracks may occur in the low refractive layer LRL, and the display quality and light efficiency of the display device DD may be deteriorated.

According to various embodiments, the display device DD may include the second step difference H2 being maintained in a range of greater than about 1.5 μm and less than about 3 μm, which may be greater than the first step difference H1, thereby reducing a risk that cracks may occur in the low refractive layer LRL and improving the display quality and light efficiency of the display device DD.

Hereinafter, a display device DD′ in accordance with an embodiment will be described with reference to FIG. 6. FIG. 6 is schematic a sectional view taken along sectional line II-II′ shown in FIG. 1 in accordance with an embodiment. The display device DD′ shown in FIG. 6 is different from the display device DD described in conjunction with FIG. 5, in that multiple bank pattern layers BF are formed. Hereinafter, descriptions of portions overlapping those described in association with FIG. 5 will be omitted.

Referring to FIG. 6, a bank pattern layer BF may include a first bank pattern layer BF_1 and a second bank pattern layer BF_2. The first bank pattern layer BF_1 may be spaced apart from the partition wall PW at a distance and may surround (or circumscribe) the partition wall PW in a plan view. The first bank pattern layer BF_1 and the partition wall PW may define (or at least partially bound) the third opening OP3. For example, the first bank pattern layer BF_1 may be disposed adjacent to the partition wall PW and closer to an edge of the display device DD′ than the partition wall PW, and may be spaced apart from the partition wall PW to define the third opening OP3.

The second bank pattern layer BF_2 may be disposed adjacent to the first bank pattern layer BF_1 and closer to an edge of the display device DD′ than the first bank pattern layer BF_1. The second bank pattern layer BF_2 may be spaced apart from the first bank pattern layer BF_1 at a distance to surround (or circumscribe) the first bank pattern layer BF_1 in a plan view. The second bank pattern layer BF_2 along with the first bank pattern layer BF_1 may define (or at least partially bound) a fourth opening OP4. For example, the second bank pattern layer BF_2 may be disposed closer to an edge of the display device DD′ than the first bank pattern layer BF_1, and may be spaced apart from the first bank pattern layer BF_1 in a plan view to define the fourth opening OP4. The fourth opening OP4 may be disposed further from the display area DA (or closer to an edge of the display device DD′) than the third opening OP3.

The first bank pattern layer BF_1 and the second bank pattern layer BF_2 may be disposed on (or in) a same layer as the partition wall PW. The first bank pattern layer BF_1 and the second bank pattern layer BF_2 may be formed through a same manufacturing process as the partition wall PW. The first bank pattern layer BF_1 and the second bank pattern layer BF_2 may include a same material as the partition wall PW. For example, the first bank pattern layer BF_1 and the second bank pattern layer BF_2 may include a black dye (or black pigment) mixed in a base resin. In some embodiments, the first bank pattern layer BF_1 and the second bank pattern layer BF_2 may have a same height as the partition wall PW. In some embodiments, the first bank pattern layer BF_1 and the second bank pattern layer BF_2 may have a height in a range of about 8 μm to about 20 μm. In some embodiments, the first bank pattern layer BF_1 and the second bank pattern layer BF_2 may have a height in a range of about 8 μm to about 15 μm.

A step difference compensation pattern layer 500 may include a first step difference compensation pattern layer 500_1 and a second step difference compensation pattern layer 500_2. The first step difference compensation pattern layer 500_1 may be disposed in the third opening OP3. The first step difference compensation pattern layer 500_1 may be disposed on (or in) a same layer as the light control pattern layer CCF. The first step difference compensation pattern layer 500_1 may be formed through a same manufacturing process as the light control pattern layer CCF. The first step difference compensation pattern layer 500_1 may include a same material as at least one of the light control pattern layers included in (or as part of) the light control pattern layer CCF.

For example, the first step difference compensation pattern layer 500_1 may be formed through a same manufacturing process as the first light control pattern layer CCF-R, and may include a same material as the first light control pattern layer CCF-R. For example, the first step difference compensation pattern layer 500_1 may include the first ink. The first step difference compensation pattern layer 500_1 may include the first base resin and the first quantum dot.

For example, the first step difference compensation pattern layer 500_1 may be formed through a same manufacturing process as the second light control pattern layer CCF-G, and may include a same material as the second light control pattern layer CCF-G. For example, the first step difference compensation pattern layer 500_1 may include the second ink. The first step difference compensation pattern layer 500_1 may include the second base resin and the second quantum dot.

For example, the first step difference compensation pattern layer 500_1 may be formed through a same manufacturing process as the third light control pattern layer CCF-B, and may include a same material as the third light control pattern layer CCF-B. For example, the first step difference compensation pattern layer 500_1 may include the third ink. The first step difference compensation pattern layer 500_1 may include the third base resin and the light scattering particle.

The first step difference compensation pattern layer 500_1 may fill (e.g., partially fill) the third opening OP3, thereby decreasing a step difference between an area overlapping the third opening OP3 in a plan view and the first bank pattern layer BF_1. The first step difference compensation pattern layer 500_1 may fill the third opening OP3 to have a height lower than a height of the first bank pattern layer BF_1. The step difference compensation pattern layer 500 and the first bank pattern layer BF_1 may have a height difference corresponding to the second step difference H2.

The second step difference H2 may be greater than the first step difference H1. For example, the second step difference H2 may be greater than about 1.5 μm and less than about 3 μm. The first bank pattern layer BF_1 and the first step difference compensation pattern layer 500_1 may have the height difference corresponding to the second step difference H2, and the low refractive layer LRL may be formed on the step difference compensation pattern layer 500 and the bank pattern layer BF.

The second step difference compensation pattern layer 500_2 may be disposed in the fourth opening OP4. The second step difference compensation pattern layer 500_2 may be disposed on (or in) a same layer as the light control pattern layer CCF. The second step difference compensation pattern layer 500_2 may be formed through a same manufacturing process as the light control pattern layer CCF. The second step difference compensation pattern layer 500_2 may include a same material as at least one of the light control pattern layers included in (or as part of) the light control pattern layer CCF.

For example, the second step difference compensation pattern layer 500_2 may be formed through a same manufacturing process as the first light control pattern layer CCF-R, and may include a same material as the first light control pattern layer CCF-R. For example, the second step difference compensation pattern layer 500_2 may include the first ink. The second step difference compensation pattern layer 500_2 may include the first base resin and the first quantum dot.

For example, the second step difference compensation pattern layer 500_2 may be formed through a same manufacturing process as the second light control pattern layer CCF-G, and may include a same material as the second light control pattern layer CCF-G. For example, the second step difference compensation pattern layer 500_2 may include the second ink. The second step difference compensation pattern layer 500_2 may include the second base resin and the second quantum dot.

For example, the second step difference compensation pattern layer 500_2 may be formed through a same manufacturing process as the third light control pattern layer CCF-B, and may include a same material as the third light control pattern layer CCF-B. For example, the second step difference compensation pattern layer 500_2 may include the third ink. The second step difference compensation pattern layer 500_2 may include the third base resin and the light scattering particle.

The second step difference compensation pattern layer 500_2 may fill (e.g., partially fill) the fourth opening OP4, thereby decreasing a step difference between an area overlapping the fourth opening OP4 in a plan view and the second bank pattern layer BF_2. The second step difference compensation pattern layer 500_2 may fill the fourth opening OP4 to have a height lower than a height of the second bank pattern layer BF_2. The second step difference compensation pattern layer 500_2 and the second bank pattern layer BF_2 may have a height difference corresponding to a third step difference H3.

The third step difference H3 may be greater than the second step difference H2. However, the third step difference H3 may be in a range of greater than about 1.5 μm and less than about 3 μm. The second step difference compensation pattern layer 500_2 and the second bank pattern layer BF_2 may have a height difference corresponding to the third step difference H3, and the low refractive layer LRL may be formed on the step difference compensation pattern layer 500 and the bank pattern layer BF.

Although not shown, the second capping layer IOL20 may be disposed over the low refractive layer LRL. The second capping layer IOL20 may cover (or overlap) the low refractive layer LRL.

The protective layer OC may be disposed over the second capping layer IOL20. The protective layer OC may cover the second capping layer IOL20. In some embodiments, an edge of the protective layer OC may overlap the sub-dam line DM-S in, for instance, the third direction DR3.

According to various embodiments, a display device in which device stability is improved may be provided, thereby improving display quality and enabling a structure rigid (or robust) against external influence(s), such as moisture.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A display device comprising:
a display area including pixels, at least one of the pixels including a light emitting element, which includes a light emitting layer;
a non-display area outside of the display area in a view in a direction;
a pixel defining layer including a first opening, at least a portion of the light emitting layer being disposed in the first opening;
a first encapsulation layer disposed in both the display area and the non-display area, at least a portion of the first encapsulation layer being disposed on the light emitting element;
a partition wall disposed on the first encapsulation layer in the display area, the partition wall including a second opening overlapping the first opening in the view;
a light control pattern layer disposed in the second opening;
a bank pattern layer disposed in the non-display area, the bank pattern layer and the partition wall at least partially bounding a third opening; and
a step difference compensation pattern layer disposed in the third opening, wherein
the partition wall and the bank pattern layer are disposed in a same layer as one another,
in the direction, a difference in height between the partition wall and the light control pattern layer is a first step difference,
in the direction, a difference in height between the bank pattern layer and the step difference compensation pattern layer is a second step difference, and
the first step difference is smaller than the second step difference.

2. The display device of claim 1, wherein the first step difference is greater than about 0 μm and less than or equal to about 1.5 μm.

3. The display device of claim 1, wherein the second step difference is in a range of about 1.5 μm to about 3 μm.

4. The display device of claim 1, wherein, in the direction, a height of the bank pattern layer is in a range of about 8 μm to about 20 μm.

5. The display device of claim 1, wherein the bank pattern layer is disposed further from the display area than the partition wall.

6. The display device of claim 1, wherein the bank pattern layer includes a same material as the partition wall.

7. The display device of claim 5, wherein
in the view, the bank pattern layer is spaced apart from the partition wall, and
in the view, the bank pattern layer circumscribes the partition wall.

8. The display device of claim 1, wherein, in the direction, a height of the step difference compensation pattern layer is smaller than a height of the bank pattern layer.

9. The display device of claim 1, wherein, in the direction, a height of the step difference compensation pattern layer is in a range of about 5 μm to about 9 μm.

10. The display device of claim 1, wherein the step difference compensation pattern layer and the light control pattern layer are disposed in a same layer as one another.

11. The display device of claim 1, wherein
the light control pattern layer includes:
a first light control pattern layer including a first quantum dot;
a second light control pattern layer including a second quantum dot; and
a third light control pattern layer including a light scattering particle,
the first quantum dot converts incident light into light in a red wavelength band,
the second quantum dot converts incident light into light in a green wavelength band,
the light scattering particle includes titanium oxide, and
the step difference compensation pattern layer includes a same material as at least one of the first light control pattern layer, the second light control pattern layer, and the third light control pattern layer.

12. A display device comprising:
a display area including pixels, a pixel among the pixels includes a first sub-pixel area, a second sub-pixel area, and a third sub-pixel area;
a non-display area outside of the display area in a view in a direction;
a light emitting element disposed in at least one of the first sub-pixel area, the second sub-pixel area, and the third sub-pixel area, the light emitting element including a first electrode, a light emitting layer disposed on the first electrode, and a second electrode disposed on the light emitting layer;
a pixel defining layer including a first opening exposing the first electrode;
a partition wall disposed in the display area, the partition wall including a second opening overlapping the first opening in the direction;
a light control pattern layer disposed in the second opening;
a bank pattern layer disposed in the non-display area, the bank pattern layer and the partition wall at least partially bounding a third opening; and
a step difference compensation pattern layer disposed in the third opening, wherein
the partition wall and the bank pattern layer are disposed in a same layer as one another,
the light control pattern layer includes:
a first light control pattern layer disposed in the first sub-pixel area;
a second light control pattern layer disposed in the second sub-pixel area; and
a third light control pattern layer disposed in the third sub-pixel area,
in the direction, a difference in height between the partition wall and the light control pattern layer is a first step difference,
in the direction, a difference in height between the bank pattern layer and the step difference compensation pattern layer is a second step difference, and
the second step difference is in a range of about 1.5 μm to about 3 μm.

13. The display device of claim 12, wherein the first step difference is smaller than the second step difference.

14. The display device of claim 12, wherein, in the direction, a height of the bank pattern layer is in a range of about 8 μm to about 20 μm.

15. The display device of claim 12, wherein
the bank pattern layer includes a same material as the partition wall, and
the bank pattern layer includes an organic material.

16. The display device of claim 12, wherein
in the view, the bank pattern layer is spaced apart from the partition wall,
in the view, the bank pattern layer is disposed further from the display area than the partition wall, and
in the view, the bank pattern layer circumscribes the partition wall.

17. The display device of claim 12, wherein
the first light control pattern layer includes a first quantum dot that converts incident light into light in a red wavelength band,
the second light control pattern layer includes a second quantum dot that converts incident light into light in a green wavelength band,
the third light control pattern layer includes titanium oxide, and
the step difference compensation pattern layer includes at least one of the first quantum dot, the second quantum dot, and the titanium oxide.

18. A display device comprising:
a display area including sub-pixel areas;
a non-display area outside of the display area in a view in a direction;
light emitting elements respectively disposed in the sub-pixel areas, each light emitting element among the light emitting elements including a first electrode, a light emitting layer disposed on the first electrode, and a second electrode disposed on the light emitting layer;
a pixel defining layer including first openings respectively exposing the first electrodes;
a partition wall disposed in the display area, the partition wall including second openings respectively overlapping the first openings in the direction;
light control pattern layers respectively disposed in the second openings;
a first bank pattern layer disposed in the non-display area, the first bank pattern layer at least partially bounding a third opening and circumscribing the partition wall in the view;
a first step difference compensation pattern layer disposed in the third opening;
a second bank pattern layer disposed in the non-display area, disposed adjacent to the first bank pattern layer, and disposed further from the display area than the first bank pattern layer, the second bank pattern layer at least partially bounding a fourth opening; and
a second step difference compensation pattern layer disposed in the fourth opening, wherein
each of the partition wall, the first bank pattern layer, and the second bank pattern layer is disposed in a same layer as one another,
the light control pattern layers include:
a first light control pattern layer disposed in a first sub-pixel area among the sub-pixel areas;
a second light control pattern layer disposed in a second sub-pixel area among the sub-pixel areas; and
a third light control pattern layer disposed in a third sub-pixel area among the sub-pixel areas,
in the direction, a difference in height between the partition wall and at least one of the light control pattern layers is a first step difference,
in the direction, a difference in height between the first bank pattern layer and the first step difference compensation pattern layer is a second step difference, and
the second step difference is in a range of about 1.5 μm to about 3 μm.

19. The display device of claim 18, wherein
in the view, the second bank pattern layer is spaced apart from the first bank pattern and circumscribes the first bank pattern layer,
the first light control pattern layer includes a first quantum dot that converts incident light into light in a red wavelength band,
the second light control pattern layer includes a second quantum dot that coverts incident light into light in a green wavelength band,
the third light control pattern layer includes titanium oxide, and
both the first step difference compensation pattern layer and the second step difference compensation pattern layer includes at least one of the first quantum dot, the second quantum dot, and the titanium oxide.

20. The display device of claim 18, wherein
in the direction, a difference in height between the second bank pattern layer and the second step difference compensation pattern layer is a third step difference, and
the third step difference is greater than the second step difference.
